(19) United States
(12) Patent Application Publication
(10) Pub. No.: US 2020/0159296 A1
(43) Pub. Date: May 21, 2020

(54) ELECTRONIC DEVICE

(71) Applicants: Inventec (Pudong) Technology Corporation, Shanghai (CN); INVENTEC CORPORATION, Taipei City (TW)

(72) Inventors: Wei-Sheng ZHU, TAIPEI CITY (TW); Sheng-Chieh HSU, TAIPEI CITY (TW); Kai-Lin KUO, TAIPEI CITY (TW); Jyun-Ji LU, TAIPEI CITY (TW)

(21) Appl. No.: 16/215,667

(22) Filed: Dec. 11, 2018

(30) Foreign Application Priority Data
Nov. 21, 2018 (CN) 201811387933.5

(51) Int. Cl. G06F 1/20; H05K 7/20

(52) U.S. Cl. CPC G06F 1/203; H05K 7/20163; G06F 2200/201; H05K 7/20172; H05K 7/20145

(57) ABSTRACT

An electronic device includes a casing wall and a heat dissipation module. The heat dissipation module includes a heat dissipation fin set, a cooling fan, and an isolation layer. The heat dissipation fin set is disposed adjacent to the casing wall, and has a first air inlet and a second air inlet. The heat dissipation fin set includes a plurality of heat dissipation fins. The cooling fan has an air outlet. The air outlet is adjacent to the first air inlet and is spaced from the second air inlet. The isolation layer has at least a part between the first air inlet and the second air inlet.

### CROSS-REFERENCE TO RELATED APPLICATION

This application claims priority to China Application Serial Number 201811387933.5, filed Nov. 21, 2018, the disclosures of which are incorporated herein by reference in their entireties.

### BACKGROUND

### Field of Invention

The present invention relates to an electronic device. More particularly, the present invention relates to an electronic device with high heat dissipation performance.

### Description of Related Art

In general, an electronic device, such as a notebook or a personal computer, needs heat dissipation modules, such as heat dissipation fins and fan module, to dissipate heat resulting from the computing components or electronic component in normal operation. With the heat dissipation module, the heat generated by the computing components or electronic components would not be accumulated in the electronic device which results in the raising temperature of the electronic device and the failure of the electronic device. In severe cases, the heat accumulation in the electronic device may damage the components in the electronic device.

However, the chassis of the electronic becomes thinner and the internal accommodating space of the chassis is reduced with the need in thinner and lighter electronic device. As such, the heat dissipation module becomes smaller along with the reduced internal accommodating space of the chassis. When the heat dissipation module becomes smaller, the heat dissipation performance of the heat dissipation module is deteriorated resulting in the raising temperature of the heat dissipation module. As the raising temperature of the heat dissipation module, the heat of the heat dissipation module is transmitted to the chassis, causing the surface temperature of the chassis to be higher and poor user experience.

### SUMMARY

Accordingly, an aspect of the disclosure is to provide an electronic device with prominent heat dissipation performance.

According to an embodiment of the disclosure, the electronic device includes a casing wall and a heat dissipation module. The heat dissipation module includes a heat dissipation fin set, a cooling fan, and an isolation layer. The heat dissipation fin set is disposed adjacent to the casing wall and has a first air inlet and a second air inlet. The heat dissipation fin set includes a plurality of heat dissipation fins. The cooling fan has an air outlet. The air outlet is adjacent to the first air inlet and is spaced from the second air inlet. The isolation layer has at least a part of the isolation layer is located between the first and second air inlets.

In an embodiment of the disclosure, the second air inlet is closer to the casing wall than the first air inlet.

In an embodiment of the disclosure, the isolation layer is disposed over the heat dissipation fins. The isolation layer is perpendicular to edges of the heat dissipation fins and extends along an arrangement direction of the heat dissipation fins.

In an embodiment of the disclosure, the isolation layer has an opening. The opening defines the second air inlet.

In an embodiment of the disclosure, the isolation layer includes insulating and gas impermeable materials.

In an embodiment of the disclosure, both of the first air inlet and the second air inlet face the air outlet of the cooling fan.

In an embodiment of the disclosure, a thickness of an end of the heat dissipation fin set away from the air outlet is greater than a thickness of an end of the heat dissipation fin set adjacent to the air outlet.

In an embodiment of the disclosure, a height of an end of the heat dissipation fin set away from the air outlet is greater than a height of an end of the heat dissipation fin set adjacent to the air outlet.

In an embodiment of the disclosure, the isolation layer is spaced from the air outlet of the cooling fan.

In an embodiment of the disclosure, a thickness of the air outlet is greater than a thickness of the air outlet.

Accordingly, the electronic device of the present disclosure is provided with the isolation layer disposed on the heat dissipation fin set and the opening is formed in the isolation layer as the second air inlet of the heat dissipation fin set. As such, air flow blown by the cooling fan is separated into two airflows. One of the airflow flows through the heat dissipation fin set to cool the heat dissipation fin set. The other airflow flows above the heat dissipation fin set to cool a chassis of the electronic device. In addition, after the airflow flowing above the heat dissipation fin set cools the chassis, the airflow above the heat dissipation fin set may be rejoined into the heat dissipation fin set through the second air inlet to further cool the heat dissipation fin set and to improve the heat dissipation performance of the heat dissipation fin set. Therefore, the configuration of the heat dissipation module not only enhances the heat dissipation performance of its own but also cools the chassis wall that user may be in contact with so as to improve user's experience.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a perspective view of a heat dissipation module according to an embodiment of the disclosure;

FIG. 2 is an exploded view of the heat dissipation module in FIG. 1; and

FIG. 3 is a partial cross-section view of an electronic device according to an embodiment of the disclosure, wherein the cross-section view of the heat dissipation module is taken along line 3-3 in FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In addition, terms used in the specification and the claims generally have the usual meaning as each terms are used in the field, in the context of the disclosure and in the context of the particular content unless particularly specified. Some terms used to describe the disclosure are to be discussed below or elsewhere in the specification to provide additional guidance related to the description of the disclosure to specialists in the art.

Phrases “first,” “second,” etc., are solely used to separate the descriptions of elements or operations with same technical terms, not intended to be the meaning of order or to limit the invention.

Secondly, phrases “comprising,” “includes,” “provided,” and the like, used in the context are all open-ended terms, i.e. including but not limited to.

Further, in the context, “a” and “the” can be generally referred to one or more unless the context particularly requires. It will be further understood that phrases “comprising,” “includes,” “provided,” and the like, used in the context indicate the characterization, region, integer, step, operation, element and/or component it stated, but not exclude descriptions it stated or additional one or more other characterizations, regions, integers, steps, operations, elements, components and/or groups thereof.

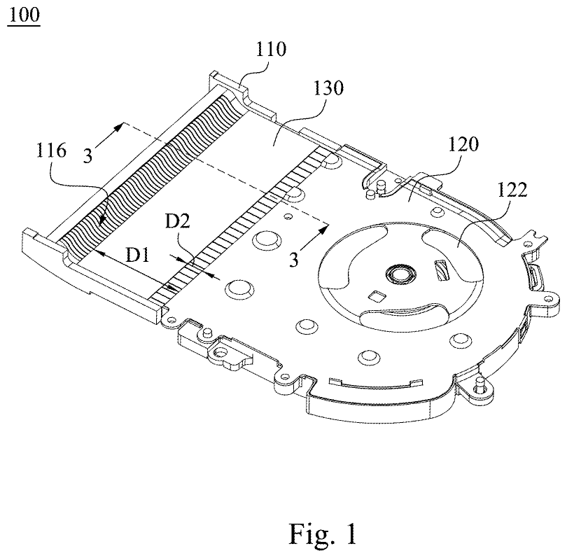

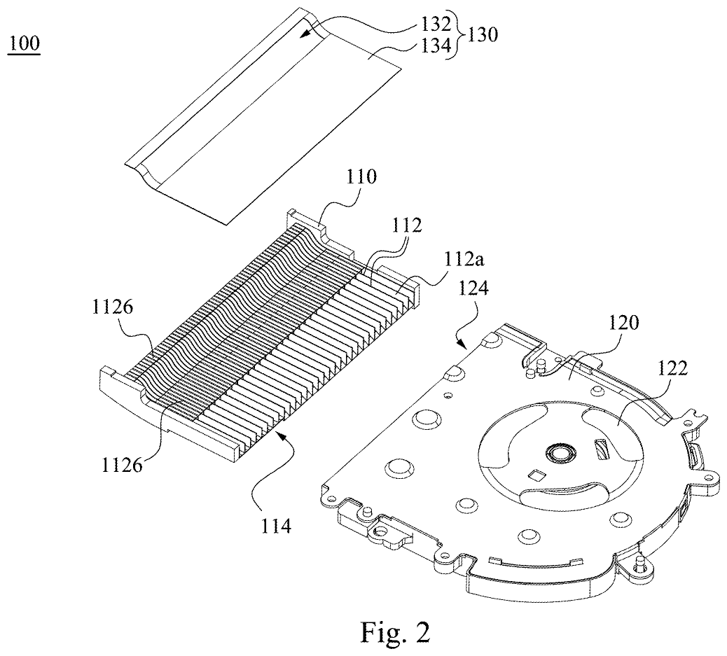

Reference is made to FIGS. 1 and 2. FIG. 1 is a perspective view of a heat dissipation module 100 according to an embodiment of the disclosure. FIG. 2 is an exploded view of the heat dissipation module 100 in FIG. 1. As shown in FIGS. 1 and 2, the heat dissipation module 100 includes a heat dissipation fin set 110, a cooling fan 120, and an isolation layer 130. The cooling fan 120 has an air inlet 122 and an air outlet 124. The heat dissipation fin set 110 includes a plurality of heat dissipation fins 112. Each of the heat dissipation fins 112 is arranged in parallel with each other and is disposed adjacent to the air outlet 124 of the cooling fan 120. Any two of the heat dissipation fins adjacent to each other are spaced apart to form a first flow path 112a. An end of the each heat dissipation fins 112 has two folding edges 1126. Each of the folding edges 1126 extends to the adjacent heat dissipation fin 112 to cover the first flow path 112a between two of the heat dissipation fins 112 adjacent to each other. The heat dissipation fin set 110 has a first air inlet 114 and a second air inlet 116. Both of the first air inlet 114 and the second air inlet 116 face the air outlet 124 of the cooling fan 120. The first air inlet 114 and the second air inlet 116 are configured to receive airflow blown by the cooling fan 120. Furthermore, the first air inlet 114 is adjacent to the air outlet 124 of the cooling fan 120. The second air inlet 116 is spaced from the air outlet 124 of the cooling fan 120 by a distance D1. The second air inlet 116 is located between the two folding edges 1126 of the each heat dissipation fins 112. Without the folding edges 1126 located at the second air inlet 116, the airflow resistance at the second air inlet 116 can be reduced. As such, the airflow is able to flow through the second air inlet 116 rapidly. Thus, the heat dissipation performance of the heat dissipation module 100 is enhanced.

In some embodiments, the cooling fan 120 is a centrifugal cooling fan, but the disclosure is not limited in this regard.

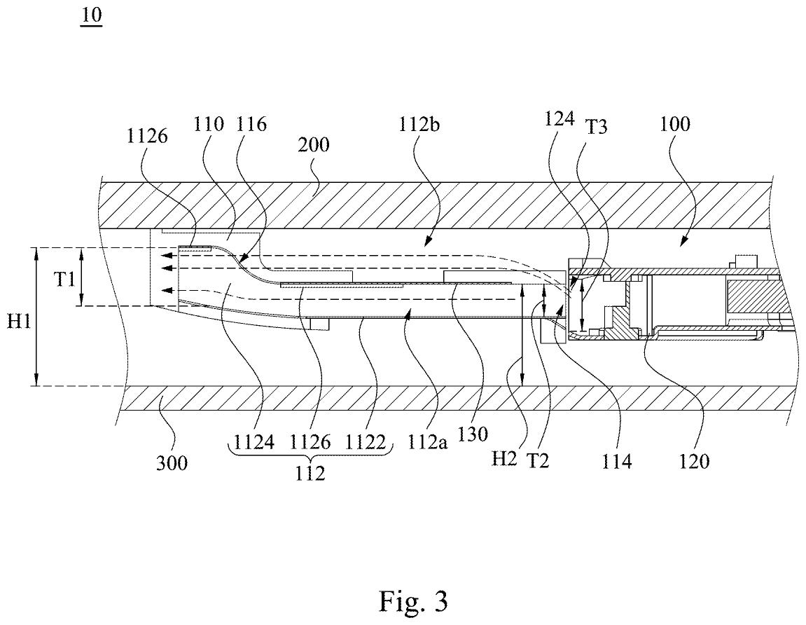

The isolation layer 130 is disposed over an edge of the heat dissipation fin set 110 close to the second air inlet 116. The isolation layer 130 is spaced from the air outlet 124 of the cooling fan 120 by a distance D2. The isolation layer 130 has an opening 132 and a cover portion 134. A part of the cover portion 134 is located between the first and the second air inlets 114, 116. The other part of the cover portion 134 surrounds the opening 132. When the isolation layer 130 is disposed on the heat dissipation fin set 110, the opening 132 overlaps the second air inlet 116. Specifically, the isolation layer 130 is perpendicular to edges of the heat dissipation fins 112 and extends along an arrangement direction of the heat dissipation fins 112. As such, the cover portion 134 of the isolation layer 130 extends along the arrangement direction of the heat dissipation fins 112 to cover the heat dissipation fins 112 and the first flow paths 112a between the heat dissipation fins 112. The opening 132 extends along the arrangement direction of the heat dissipation fins 112 to define the second air inlet 116. A second flow path 112b is formed between the isolation layer 130 and an upper casing wall 200 (as shown in FIG. 3). Further, the isolation layer 130 is located between the first and the second flow paths (112a, 112b) to prevent the airflow through the first flow paths 112a from interfering with the airflow through the second flow path 112b. Thus, the isolation layer 130 prevents the happening of turbulence between the first and the second flow paths (112a, 112b).

In some embodiments, material of the isolation layer 130 includes insulating and gas impermeable material, for example polyester film, but the disclosure is not limited in this regard.

Reference is made to FIG. 3. FIG. 3 is a partial cross-section view of an electronic device 10 according to an embodiment of the disclosure, wherein the cross-section view of the heat dissipation module 100 is taken along line 3-3 in FIG. 1. In the embodiment, the electronic device 10 can be a laptop, but the disclosure is not limited in this regard. As shown in FIG. 3, the electronic device 10 includes the upper casing wall 200, a bottom casing wall 300, and the heat dissipation module 100. The heat dissipation module 100 is installed between the upper casing wall 200 and the bottom casing wall 300. The heat dissipation fin set 110 is adjacent to the upper casing wall 200. The each heat dissipation fins 112 further has a body portion 1122 and a bending portion 1124. The body portion 1122 is adjacent to the air outlet 124 and extends away from the air outlet 124. The bending portion 1124 is connected to the body portion 1122 and bends towards the upper casing wall 200 relative to the body portion 1122. As such, an end of the heat dissipation fin set 110 away from the air outlet 124, that is the end where the second air inlet 116 is located, has a thickness T1. The thickness T1 is greater than a thickness T2 of an end of the heat dissipation fin set 110 adjacent to the air outlet 124.

Further, an end of the each heat dissipation fins 112 away from the air outlet 124 has a height H1 measured from a side of the each heat dissipation fins 112 adjacent to the upper casing wall 200 to the bottom casing wall 300. An end of the each heat dissipation fins 112 adjacent to the air outlet 124 has a height H2 measured from the side of the each heat dissipation fins 112 adjacent to the upper casing wall 200 to the bottom casing wall 300. The heat H1 is greater than the height H2. As such, the second air inlet 116 is closer to the upper casing wall 200 relative to the first air inlet 114. One of the two folding edges 1126 is connected to the body portion 1122 and extends towards the adjacent heat dissipation fin 112 relative to the body portion 1122. The other folding edge 1126 is connected to the bending portion 1124 and extends towards the adjacent heat dissipation fin 112 relative to the bending portion 1124.

Moreover, the air outlet 124 of the cooling fan 120 has a thickness T3. The end of the heat dissipation fin set 110 adjacent to the air outlet 124 has a thickness T2 that is the thickness T2 of the first air inlet 114. The thickness T3 is greater than the thickness T2. Thereby, a portion of airflow blew by the cooling fan 120 flows into the first flow paths 112a between the heat dissipation fins 112 via the first air inlet 114 to dissipate the heat of the heat dissipation fins 112. The folding edges 1126 of the heat dissipation fins 112 increase contact area between the heat dissipation fins 112 and the airflow, thereby further promoting the heat dissipation performance.

The other portion of airflow blown by the cooling fan 120 flows through the upper casing wall 200 via the second flow path 112b to cool the upper casing wall 200. In addition, the airflow through the second flow path 112b further flows into the heat dissipation fin set 110 via the second air inlet 116 with less airflow resistance after it cools the upper casing wall 200. Thereby, the airflow further help the heat dissipation fin set 110 to dissipate the heat so that the heat dissipation performance of the heat dissipation fin set 110 is improved. In this way, cooling the chassis of the electronic device 10 and the heat dissipation performance enhancement of the heat dissipation module 100 can be achieved at the same time. The heat accumulation in the heat dissipation module 100 is avoided so that the temperature of the electronic device would not be raised and the failure of the electronic device 10 is avoided.

According to the foregoing recitations of the embodiments of the disclosure, it can be seen that the electronic device of the present disclosure is provided with the isolation layer disposed on the heat dissipation fin set and the opening is formed in the isolation layer as the second air inlet of the heat dissipation fin set. As such, airflow blown by the cooling fan is separated into two airflows. One of the airflow flows through the heat dissipation fin set to cool the heat dissipation fin set. The other airflow flows above the heat dissipation fin set to cool the chassis wall of the electronic device. In addition, after the airflow flowing above the heat dissipation fin set cools the chassis wall, the airflow above the heat dissipation fin set may be rejoined into the heat dissipation fin set through the second air inlet to improve the heat dissipation performance of the heat dissipation fin set. Therefore, the configuration of the heat dissipation module not only enhances the heat dissipation performance of its own but also cools the chassis wall that the user may be in contact with so as to improve user's experience.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electronic device, comprising:
a casing wall; and
a heat dissipation module, comprising:
a heat dissipation fin set, disposed adjacent to the casing wall, having a first air inlet and a second air inlet, and comprising a plurality of heat dissipation fins;
a cooling fan having an air outlet, wherein the air outlet is adjacent to the first air inlet and spaced from the second air inlet; and
an isolation layer having at least a part between the first and second air inlets.

2. The electronic device of claim 1, wherein the second air inlet is closer to the casing wall than the first air inlet.

3. The electronic device of claim 1, wherein the isolation layer is disposed over the heat dissipation fins and, perpendicular to edges of the heat dissipation fins, and extends along an arrangement direction of the heat dissipation fins.

4. The electronic device of claim 1, wherein the isolation layer has an opening, which defines the second air inlet.

5. The electronic device of claim 1, wherein the isolation layer comprises insulating and gas impermeable materials.

6. The electronic device of claim 1, wherein both of the first air inlet and the second air inlet face the air outlet of the cooling fan.

7. The electronic device of claim 1, wherein a thickness of an end of the heat dissipation fin set away from the air outlet is greater than a thickness of an end of the heat dissipation fin set adjacent to the air outlet.

8. The electronic device of claim 1, wherein a height of an end of the heat dissipation fin set away from the air outlet is greater than a height of an end of the heat dissipation fin set adjacent to the air outlet.

9. The electronic device of claim 1, wherein the isolation layer is spaced from the air outlet of the cooling fan.

10. The electronic device of claim 1, wherein a thickness of the air outlet is greater than a thickness of the air outlet.
